(19) United States
(12) Patent Application Publication
(10) Pub. No.: US 2022/0127751 A1
(43) Pub. Date: Apr. 28, 2022

(54) LARGE AREA SINGLE CRYSTAL DIAMOND

(71) Applicant: Robert C. Linares, Hingham, MA (US)

(72) Inventor: Robert C. Linares, Hingham, MA (US)

(21) Appl. No.: 17/452,480

(22) Filed: Oct. 27, 2021

Related U.S. Application Data
(60) Provisional application No. 63/106,263, filed on Oct. 27, 2020.

(51) Int. Cl. C30B 25/20; C30B 25/18; C30B 25/04; C30B 29/04

(52) U.S. Cl. CPC C30B 25/20; C30B 29/04; C30B 25/04; C30B 25/186

(57) ABSTRACT

A method includes positioning a designated rectangular single crystal diamond seed in a diamond growth reactor, the designated single crystal diamond seed having a (001) plane, with the edges being (001) planes and corners are pointed in the <110> direction, positioning a pair of blocking seeds on opposite edges of the designated seed, and growing diamond of the designated seed and blocking seeds, wherein lateral single crystal growth occurs laterally from the designated seed.

### RELATED APPLICATION

This application claims priority to U.S. Provisional Application Ser. No. 63/106,263 (entitled Large Area Single Crystal Diamond, filed Oct. 27, 2020), which is incorporated herein by reference.

### BACKGROUND

Single crystal diamond has become a material of great important for use in semiconductor devices, quantum devices, optical windows, gemstones, cutting tools and many other devices and applications. Single crystal diamond was originally produced by the high pressure, high temperature method (HPHT) method (H. Strong U.S. Pat. No. 2,947,609, 1960) and others. These first crystals were small, but soon became the basis for a worldwide industry for producing diamond powder for industrial cutting and grinding purposes. However, because of the high temperature and pressure required, the practical size for large scale production was limited to 5-8 mm square and a few mm thick. The HPHT method also resulted in the incorporation of high levels of nitrogen. Therefore, HPHT grown diamond lacked the size and purity required for electronic, optical and quantum device development and manufacturing. Diamond was deposited at low pressures on non-diamond substrates by the Chemical Vapor Deposition (CVD) process (M. Kamo, “Diamond Synthesis From Gas Phase in Microwave Plasma” J. Crystal Growth”, (1983)), (I. Watanabe, “Low-Temperature Synthesis of Diamond Films in Thermoassisted RF Plasma Chemical Vapor Deposition”, 1992 The Japan Society of Applied Physics). This produced polycrystalline diamond films. CVD grown polycrystalline diamond is currently used to produce diamond coated cutting tools, wear parts and a large number of other applications. CVD diamond was deposited on single crystal natural and HPHT grown single crystal grown plates to produce single crystal, homoepitaxial diamond plates having properties identical to natural single crystal diamond (R Linares, “Properties of Large Single Crystal Diamond”, Diamond and Related materials, 1999—Elsevier). Plates up to 8 mm square by 1 mm thick were grown. Since that time, CVD homoepitaxial diamond growth has become the preferred method of deposition of diamond for optical, electronic, and quantum devices as well as gemstones. Because of the ability to control the growth environment in CVD growth chambers, the properties of the resulting diamond such as purity, doping control, optical transparency, electrical resistivity, crystal perfection, isotope concentration are possible to a level seen only in the semiconductor industry. Nevertheless, the limited size and perfection of single crystal substrates available at the present time remains a substantial barrier to the production of diamond devices of all types and to the efficient production of diamond gemstones, optics and cutting tools. Furthermore, because of the relative fragility of thin large size diamond seed crystals/plates, the yield loss and cost of producing and processing CVD diamond devices goes up dramatically with size. This disclosure will present methods to grow, handle and fabricate single crystal diamond substrates of increased size, which are appropriate for production of the afore mentioned devices and other articles. This process is also sustainable on its own, and eliminates the need for HPHT seed crystals.

Many approaches have been taken to produce large area diamond substrates and separate them from the underlying substrates. Many efforts have been made to create a mosaic of diamond crystals by placing a number of precisely sized and oriented diamond plates side by side in a two-dimensional array. These arrays were placed in a CVD diamond growing chamber and diamond was grown on the array. In the process, diamond growth occurs both vertically from the seed surface and laterally from the seed edges to connect all the seed crystals in a continuous, continuous mosaic diamond surface. This work (M. Vichr, U.S. Pat. No. 5,753,038 (1998), “Method for growth of industrial crystals”), (N. Fujimori, U.S. Pat. No. 5,474,021 (1995), “Epitaxial diamond from the vapor phase”) and (J. Giling, Diamond and related materials, vol 4, issue 1, 15 May 1995, “Mosaic growth of diamond”), produced mosaic diamond crystal plates which contained island of high-quality single crystal diamond connected by boundaries of defective diamond. These defective boundary layers propagated vertically continuously through successive generations of diamond mosaic plates. The area of high-quality material was therefore limited by the size of the original diamond mosaic blocks and the skill of the fabricator in obtaining suitable orientation of the blocks. The method has been useful for the production of cutting tools, gemstones and small optical and electronic parts. More recently mosaics having individual block sizes of 8-10 mm square have been produced and grown into a mosaic of 40 to 50 mm square and larger. H. Yamada, Appl Phys Lett 104, 102110 (2014), “A 2-in. mosaic wafer made of single crystal diamond”. The method is limited use to where such areas are acceptable for device such as optics, integrated circuits of quantum devices. The method also has limitations in size due to fragility of the resulting mosaics and problems of separation as the size of mosaic grew larger.

For larger device areas another method is required.

Y. Mokuno, “High rate homoepitaxial growth of diamond by microwave plasma CVD with nitrogen addition”, Diamond and related Materials, (2006), Elsevier, increased the size of a CVD single crystal by growing on a seed crystal to a desired thickness, turning the resulting crystal 90 degrees and growing to a new thickness and repeating the process through several steps of growth and fabrication. This process is limited by the formation of defective material at the corners and cracking.

M. Vichr, U.S. Pat. No. 5,753,038 (1998), “Method for growth of industrial crystals” devised a method to remove the grown crystal layer from the mosaic seed. He placed many highly oriented cvd plates side by side in a two-dimensional array, placed the array in a cvd diamond grower grew cvd diamond on the array. He then deposited silica onto the new cvd surface, and etched holes in the silica surface. He then grew diamond up through the silica holes (forming diamond pillars) and then laterally over the silica remaining to connect all the growth into a single mosaic diamond wafer. The wafer with the substrate is removed, placed hydrofluoric acid to etch way the silica intermediate layer. The growth layer is then separated from seed layer by applying pressure at the interface between the seed and the new growth to fracture the pillars and achieve separation. This method, while workable, has many process steps, is complicated, gives poor yields and has not achieved widespread implementation (that we know of at this time).

In another separation method, (M Marchywaka, U.S. Pat. No. 5,587,210A (1996), “Growing and Releasing Diamond”) irradiate single diamond with carbon ions (via an ion implanter) and produced a damaged layer beneath the diamond surface. He then grew a cvd diamond epitaxial layer on top of the damage layer and then removed the damage layer by heat treatment or by oxidation under electrolysis. Either method of removal is quite successfully, except that ion implantation is very expensive, time consuming and the implant must be performed at low temperature and/or low dose rate to prevent heating and in-situ annealing out of the damage with no subsequent lift off possible. H. Yamada, Appl Phys Lett 104, 102110 (2014), “A 2-in. mosaic wafer made of single crystal diamond” combined mosaic growth with lift off by ion implantation to obtain mosaic plates of up to 40×60 mm.

Another method of removing a substrate from its seed is by diamond sawing. This a very old technique, P. Grodzinski, “Diamond Technology”, NAG Press LTD., London (1956) and it is widely used in the gem industry. However, it is a slow process and results in high kerf loss at large size crystals and is therefore not useful for sawing large diamond crystals. An improvement over diamond sawing method is using high power laser sawing. Laser sawing and water jet laser sawing is the prime method of removing diamond growth from substrates in industry today. (S K Sudheer, “Characterization of laser processed single-crystal natural diamond using micro-Raman spectroscopic investigations”, Journal of Raman Spectroscopy, 18 Dec. 2007) Laser sawing is ideal for small to medium size substrates. However, the issues of surface damage and kerf loss make it unsuitable for sizes greater than 2 centimeters. Water jet laser cutting decreases kerf loss but then fragility and handling issues become dominant. In short, at this time there is no sure way of producing and separating large area diamond wafers from their substrates.

Another method which should not be ignored for diamond device and gem production is heteroepitaxial growth on non-diamond substrates. In this method, diamond is deposited on highly oriented iridium layers which has been deposited on oxide substrates such as sapphire strontium titanate, cubic zirconia or MgO or on a semiconductor such as silicon, M. Schreck, Sci. Rep. 2017, 7, 44462, or silicon carbide. The resulting diamond is highly disoriented on the micrometer level and it is unsuitable for most single crystal diamond devices. But for devices where misorientation can be allowed, heteroepitaxy would permit a rapid advance to large substrates. However, issues of cracking still have to be solved even on a small level.

A further improvement in heteroepitaxy combined improved growth of diamond on MgO crystals with seed separation (from the seed wafer) and regrowth on the new seed. In this method, metal dots were deposited on a heteroepitaxial diamond surface. The diamond surface was then etched by reactive ion etching. The metal protected the diamond surface under it from etching, the plasma etched the diamond only, to form diamond pillars of nanometer (nano-wire) dimensions. The substrate containing the pillars was reintroduced into the growth chamber and growth initiated. The new diamond growth spreads vertically and horizontally, connecting the diamond nanowires into a diamond crystal of improved quality over the initial growth. The new growth is separated from the original growth by oxidation. The crystal quality obtained is significantly improved over the original heteroepitaxy, but still the quality is lower than pure single crystal diamond.

The properties of the diamond crystals can be adjusted and improved after growth in order to meet device requirements. It has been shown that improvement of physical properties such as strain can be accomplished by heating diamond to a high temperature under high pressure. Furthermore, it has been shown that the color of diamond, including the presence or absence of N-V centers, can be adjusted by the heating diamond to high temperatures, with or without high pressure.

### SUMMARY

A method includes positioning a designated rectangular single crystal diamond seed in a diamond growth reactor, the designated single crystal diamond seed having a (001) plane, with the edges being (001) planes and corners are pointed in the <110> direction, positioning a pair of blocking seeds on opposite edges of the designated seed, and growing diamond of the designated seed and blocking seeds, wherein lateral single crystal growth occurs laterally from the designated seed.

### BRIEF DESCRIPTION OF THE DRAWINGS

FIG. 1A is a top view of a single crystal diamond seed according to an example embodiment.

FIG. 1B is a top view of the single crystal diamond seed of FIG. 1A showing some growth according to an example embodiment.

FIG. 1C is a top view of the single crystal diamond seed of FIG. 1A showing further growth according to an example embodiment.

FIG. 2A is a top view of a designated seed with blocking seeds according to an example embodiment.

FIG. 2B is a top view of the designated seed with blocking seeds of FIG. 2 A with some growth according to an example embodiment.

FIG. 2C is a top view of the designated seed with blocking seeds of FIG. 2 A with full growth according to an example embodiment.

FIG. 2D is a top view of the designated seed with blocking seeds of FIG. 2 A illustrating lateral single crystal growth of the designated seed according to an example embodiment.

FIG. 2E is a top view of the separated designated seed with lateral growth according to an example embodiment.

FIG. 3A is a top view of the separated designated seed of FIG. 2E with blocking seeds according to an example embodiment.

FIG. 3B is a top view of the separated designated seed of FIG. 2E with blocking seeds with full growth according to an example embodiment.

FIG. 3C is a top view of the separated designated seed of FIG. 2E with blocking seeds illustrating lateral single crystal growth of the separated designated seed of FIG. 2E according to an example embodiment.

FIG. 3D is a top view of the separated designated seed with lateral growth according to an example embodiment.

FIG. 4A is an end view and a side view of a designated seed with blocking seeds according to an example embodiment.

FIG. 4B is an end view and a side view of a designated seed with blocking seeds and initial growth according to an example embodiment.

FIG. 4C is an end view and a side view of a designated seed with blocking seeds and full growth according to an example embodiment.

FIG. 4D is an end view and a side view of a designated seed with blocking seeds with a separation layer according to an example embodiment.

FIG. 4E is a side view and a side view of a designated seed with blocking seeds with a separation layer and new growth according to an example embodiment.

FIG. 4F is a side view and a side view of a designated seed with blocking seeds with new growth separated according to an example embodiment.

FIG. 5A is a top view illustrating new growth separated from a seed according to an example embodiment.

FIG. 5B is a top view of new growth with edge blocking seeds according to an example embodiment.

FIG. 5C is a top view of new edge growth according to an example embodiment.

FIG. 5D is top view illustrating the result of laser trimming according to an example embodiment.

FIG. 5E is a top view of a designated seed laser trimmed to original size according to an example embodiment.

FIG. 6A is an edge view of dislocations in an original seed according to an example embodiment.

FIG. 6B is an edge view of dislocations in a first lateral growth according to an example embodiment.

FIG. 6C is a top view of dislocations in a second lateral growth according to an example embodiment.

FIG. 7A is a side view of a single crystal diamond substrate according to an example embodiment.

FIG. 7B is a side view of the single crystal diamond substrate of FIG. 7A with a pattern according to an example embodiment.

FIG. 7C is a side view of a single crystal diamond substrate illustrating nanowires formed based on the pattern of FIG. 7B according to an example embodiment.

FIG. 7D is a side view of a single crystal diamond substrate with further single crystal growth on top of the nanowires of FIG. 7C according to an example embodiment.

FIG. 7E is a side view of a single crystal diamond substrate separated from the single crystal growth of FIG. 7D according to an example embodiment.

FIG. 8A is a side view of a single crystal diamond substrate grown on nanowires according to an example embodiment.

FIG. 8B is a side view of a handle attached to the substrate of FIG. 8A according to an example embodiment.

FIG. 8C is a side view of the handle and substrate of FIG. 8B separated from a further substrate according to an example embodiment.

FIG. 9 is a side view of multiple layers grown on a substrate attached to a handle according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

Various embodiments are directed to the growth of large area diamond substrates for semiconductor and quantum devices, cutting tools, optical devices, gemstones and other applications, as well as the handling and removal of such substrates from their original substrate. One method employs a series of lateral growth steps to produce single crystal diamond of large size, substrate removal, such as by nanowire production or other method, single crystal growth and subsequent removal combined with the use of polycrystalline diamond wafers to provide mechanical support to the single crystal diamond wafer during handling, polishing, device deposition and fabrication and packaging. The method is self-sustaining and removes the need for natural or high pressure high temperature (HPHT) diamonds for seed crystals.

In one embodiment, It can be appreciated that many of these composites of single crystal and polycrystalline diamond can be grown simultaneously in a large diamond growing chamber resulting in production of a large number of large single crystal diamond wafers per week. This would move single crystal diamond from a laboratory curiosity, to an industrial scale process which in turn would enable a robust diamond device manufacturing capability to develop. It should be noted that once a large area of homoepitaxial single crystal diamond is achieved, (since the vertical growth rate for both homoepitaxial single crystal and heteroepitaxial diamond will be the same or close) there is no cost advantage to heteroepitaxial diamond versus homoepitaxial diamond (and the crystal quality of homoepitaxial diamond is currently believed to always be higher).

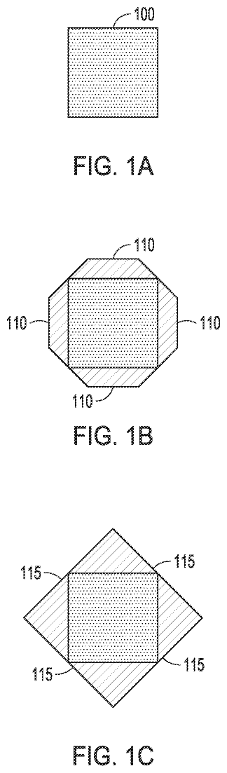

The growth of large area diamond single crystals by the HPHT method is currently limited by the size of HPHT growers currently available and the time required to grow a diamond crystal to a suitable large size. CVD single crystal growth is currently limited by the size of HPHT or natural diamond seed crystals which are available and certain features of CVD growth. FIG. 1A shows the crystallographic orientation of a typical HPHT seed 100 being used for growth of a CVD layer. The visible plane of the seed 100 is designated a (001) plane, the edges are (001) planes and the corners are pointed in the <110> direction. Under the growth conditions used to date, the (001) plane grows the fastest (vertically out of the page) and grows out of existence, while the <110> grows slowly and persists even when the <001> has grown out of existence. FIG. 1B shows the early stages of growth at 110 and FIG. 1C shows the <001> direction growth fully grown at 115 out of existence. Two observations may be made of this growth: 1. The growth in the (001) plane is highly perfect and faceted, and 2. The growth in the (110) plane is highly defective. The resulting shape appears to be a turning of the orientation by 45 degrees, but it is really an annihilation of one plane (the (001) plane, and the dominance of another plane, the (110) plane, however defective). This growth behavior has so far been dominant in current CVD diamond growth conditions and has prevented enlargement of diamond seeds by lateral growth in all directions.

Selective Lateral Growth.

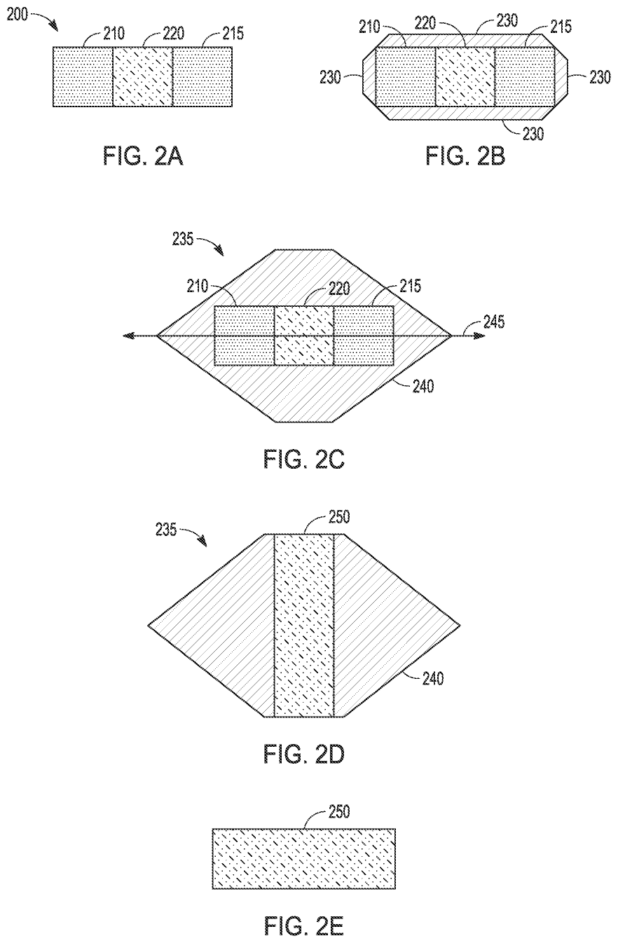

In one embodiment, Selective Lateral Growth (SLG) is used to form a large area diamond substrate. At least three diamond seed crystals are placed end to end while touching each other, in a diamond growth reactor as shown in FIG. 2A at 200. In one embodiment, the edges of the seed crystals are placed as closely parallel as can be cone with laser sawing, perhaps 0.1 degrees. One advantage of using the blocking sees is that the edge orientation is relatively unimportant to within a few degrees.

The seed crystals are subjected to a temperature, pressure and gas composition commonly used for CVD diamond growth. Two of the three seeds are referred to as end or blocking seeds 210, 215, since they will block the growth of defective diamond onto a center seed 220. The center seed is called the designated seed 220 since it will be designated for expansion in size. This nomenclature shall be used throughout. The center seed 220 may have the same orientation and nomenclature as seed 100.

FIG. 2B shows growth after several hours with smooth growth 230 in the <001> directions and rough growth in the <110> directions. FIG. 2C shows a fully-grown seed bar 235 with new growth generically represented at 240. New growth 240 comprises growth in which the (001) planes in a long axis 245 of the three seeds 210, 220, 215 placed end to end, have been grown out of existence and is replaced by the defective (110) planes. By contrast growth from the “designated seed”, in the (001) plane (toward the viewer) which is perpendicular to the long axis 245, remains smooth with no sign of rough <110> growth. This new growth is a single crystal extension of the “designated seed”. It contains no mosaic grain boundaries and is even improved in perfection over the original designated seed 220.

FIG. 2D shows the growth from FIG. 2C, while delineating the area of highly perfect laterally extended single crystal 250. FIG. 2E shows the extended single crystal 250 rotated 90 degrees after cutting it out of the fully-grown seed bar 235. Single crystal 250 may then be used as a designated seed for further growth. It is possible and desirable to increase the number of “designated seeds” in a run while maintaining two “blocking seeds”. This will increase the number of new “designated seeds” in a run and speed up development of larger and larger single crystals.

The orientation of the adjacent blocking seeds is not critical since we are only concerned with the lateral extension of an individual crystal from the designated seeds to achieve increased area.

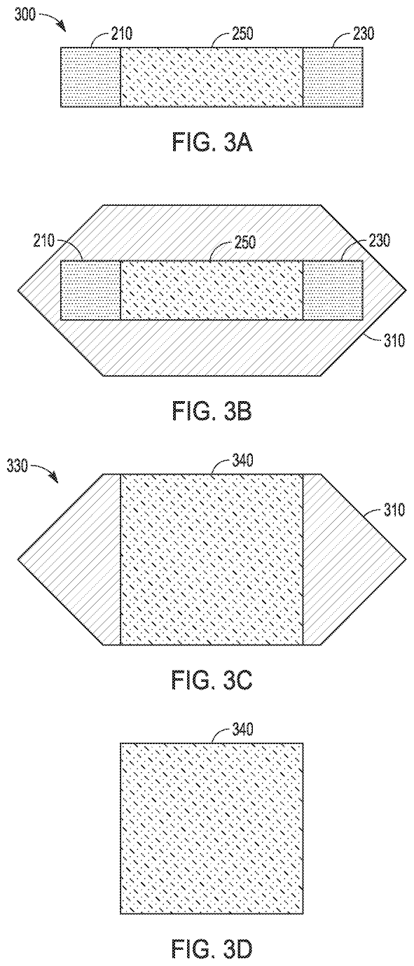

This process can be continued to further increase the single crystal area. In FIG. 3A at 300, the new crystal 250 becomes a new designated seed with two blocking seeds 210 and 230. The same size blocking seeds may be used where the original designated seed 220 was square, or new block seeds may be used if the edge of the designated seed 350 adjacent the blocking seeds is longer than the original edges of designated seed 220.

FIG. 3B shows a fully grown out crystal 310. FIG. 3C at 330 shows the fully grown out crystal with the new enlarged single crystal 340 having an area that may be approximately four times the area of the original designated seed 220. FIG. 3D shows the laser cut large single crystal 340. The large area of crystal 340 is now fully replicable and may provide the basis for future iterations of growth to provide even greater crystal wafer sizes. The ends of the bar (blocking seed 210, designated seed 250, and blocking seed 230) which originated from the “blocking seeds”, can be fabricated to provide additional “blocking seeds” or used for other purposes where single crystal substrates are needed.

Crystal Separation:

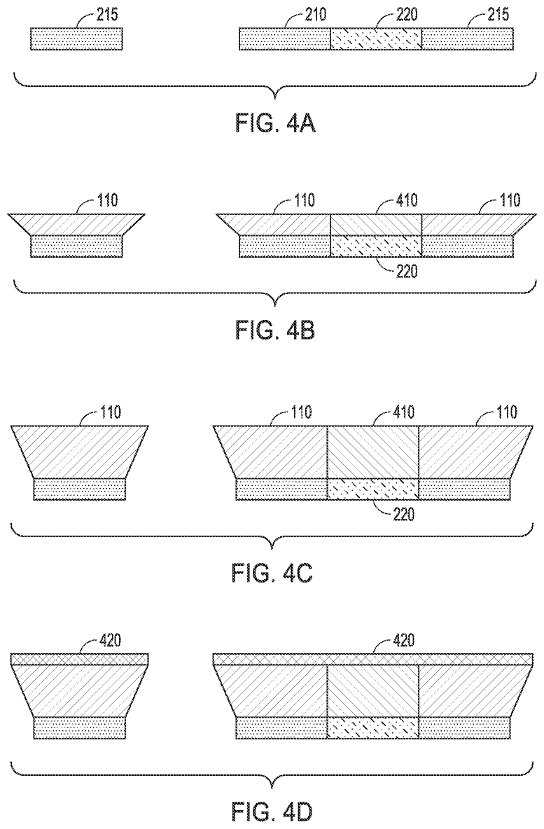

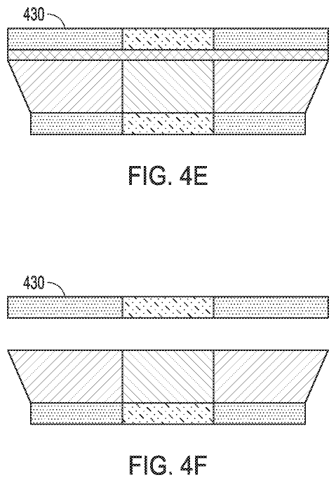

It should be appreciated that any of the previous steps can be interrupted, a separation layer grown and a new single crystal layer grown and separated to form a new family of seeds, both blocking and designated, for future or parallel use in growing larger single crystal diamonds. FIGS. 4A-F illustrate side view and end views of vertical growth of a three-piece seed bar. FIG. 4A shows the original three bars. FIG. 4B illustrates some growth, including single crystalline growth 410. FIG. 4C illustrates n-growths. FIG. 4D illustrates a separation layer 420. FIG. 4E illustrates a regrowth layer 430. FIG. 4F illustrates the regrowth layer 430 fully separated and ready to use for subsequent enlargement or device use. The figures referenced in this paragraph illustrate the vertical extensions of the three original seeds.

Seed Size Preservation

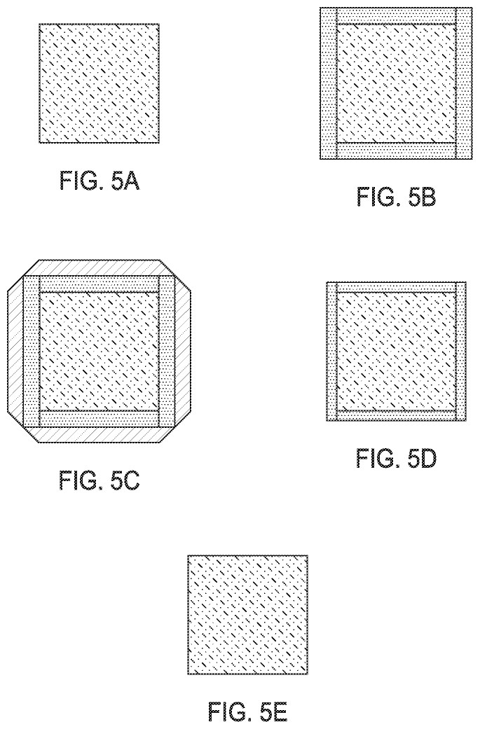

Seed size can be preserved by the application of blocking seeds on all four edges of the desired seed. FIG. 5A shows a typical enlarged seed which becomes a new “designated seed”. FIG. 5B shows the seed with four blocking seeds. FIG. 5C shows original seed with blocking seed and lateral growth. FIG. 5D shows partial laser trimming to remove new growth. FIG. 5E shows final trimming to original or any smaller size. By further iteration this method will provide an endless supply of pure CVD single crystals for device, fabrication, seed production or further seed enlargement. A separation layer can be inserted at the end of FIG. 5C and the process repeated for several iterations. On laser trimming down through all the layers, many wafers can be released simultaneously, with decreased labor and material loss. It can be appreciated that many of these stacks can be grown on simultaneously in a sufficiently large grower. Therefore, it will be possible to achieve in production of many large area single crystal diamond substrates in one day. This output would rival the output of heteroepitaxial diamond on a daily output and cost basis, while providing a superior product.

Dislocation Reduction:

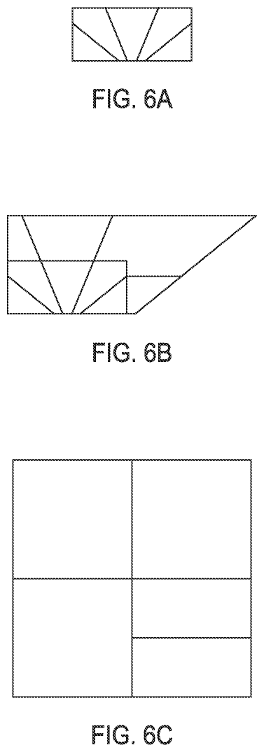

Dislocations in CVD single crystal diamond usually originate from the original HPHT diamond seed or from polishing imperfections in the preparing the natural, HPHT or CVD diamond seeds. FIG. 6A shows an edge view of a HPHT (or CVD) diamond wafer with dislocation emanating from a central dislocation source. FIG. 6B shows top and lateral growth with dislocations propagating perpendicular into the top layer and continuously emerging into the surface, while dislocations propagating into the edge growth are trapped within that growth and lost to future interactions. FIG. 6C shows that subsequent edge growth has no (or diminished) dislocation paths which can emerge on a surface. Therefore, SLG through several generations can lead to significand reductions and potential elimination of dislocations in CVD diamond.

Separation of New Growth from Substrate:

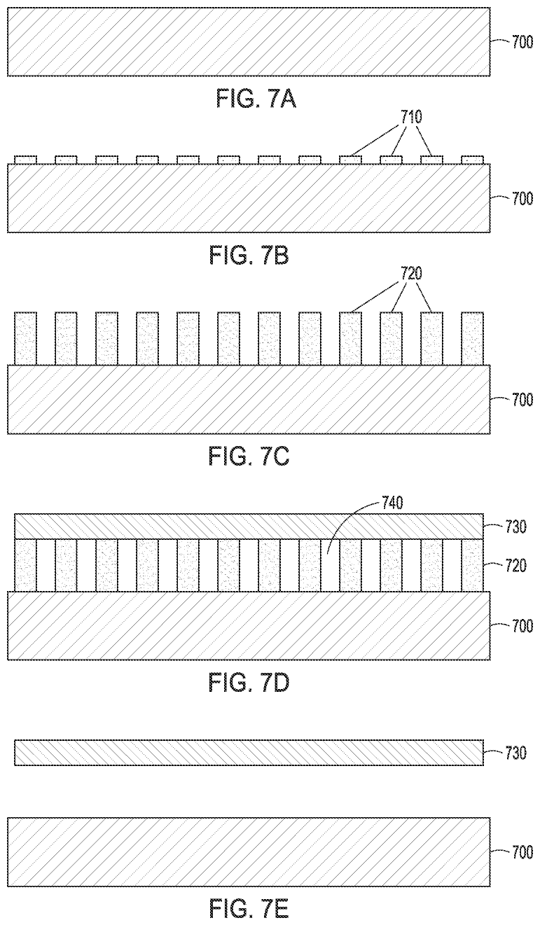

Separation of growth from substrate can be accomplished be several methods as described earlier. In this case we describe the use of diamond-nano-wires, however any of the other separation methods can be used as described previously. To form vertical diamond-nano-wires, a polished single crystal diamond wafer 700 is used as shown in FIG. 7A. An array of metal (or other) nanodots 710 is deposited on the diamond surface FIG. 7B. The surface is etched in an oxygen (or other suitable) plasma. The diamond is etched alongside the metal nanodots to produce vertical diamond nanowires 720 as shown in FIG. 7C. The assembly is placed in a diamond growth reactor and diamond 730 is grown over and connecting the nanowires 720 leaving a hollow space 740 under and between the nanowires as shown in FIG. 7D. Finally, the entire assembly is placed in an oxidizing environment which attacks the diamond nanowires 720 releasing the newly grown substrate 720 as shown in FIG. 7E. Note that the figures are not to scale to facilitate ease of illustration. The dimensions of the nanowires in one embodiment are 50 nm wide and 100 nm high with the newly grown substrate being significantly thicker than 100 nm.

Device Substrate on Polycrystalline Diamond:

The newly separated, large area diamond substrate will be thin and fragile. The process steps involved in the production of diamond substrate wafers, and diamond devices such as semiconductor devices, quantum devices and others, may require handling and transport of diamond substrates in a wide range of operating environments. Holders for the diamond substrates may need to operate over the temperature range of the process while providing physical support and protection from corrosive gasses or plasma. Of particular concern is the need to avoid stress during processing due to chemical reaction or differential thermal expansion coefficient. This is particularly true when processing thin diamond films, whether devices or in-process single crystal substrates. Thin diamond films are fragile, especially in large areas, and it is important for their survival in processes chemicals, gasses and wafer handling equipment where accurate transport of wafers from one step to another is required. Some of the required attributes for a diamond substrate holder are:

Physical Strength, Chemical Resistance, Matching Thermal Expansion Coefficient Over the Processing Range, and Affordability.

Polycrystalline diamond: The material for a holder which meets all of the criteria for most of these applications is polycrystalline diamond. Polycrystalline diamond meets all the requirements of thermal expansion coefficients and chemical activity of single crystal diamond. Polycrystalline diamond can be used to hold, support and carry thin diamond films which are generated by implant and liftoff, diamond growth on nanowires, mechanical grinding and polishing, plasma etching or some other thinning process. The polycrystalline diamond can be made by CVD or by HPHT processes. Polycrystalline diamond would be strong enough to pass through conventional wafer handling equipment.

Fused Quartz: Fused quartz has a very low thermal expansion coefficient and would be suitable for use as a substrate for diamond in many applications. It should not be used at elevated temperatures where it would soften, or in plasma etching where etching would release silicon which might have harmful effects on device properties.

Improved substrate holders for diamond processing may be used to perform one or more of the following functions:

Hold a single crystal diamond during implantation and lift-off;

Hold a single crystal diamond after nanowire formation and single crystal growth;

Hold a single crystal diamond during fabrication, polishing or etching;

Hold a single crystal diamond during subsequent additional cvd growth, metallization, or other processing for device or circuit production;

Hold a single crystal diamond during subsequent growth of additional doped layers, including without limitation N, Si, ¹³C, P or other elements; and

Hold a single crystal diamond during treatments involving heat, pressure, irradiation, annealing or other conditions.

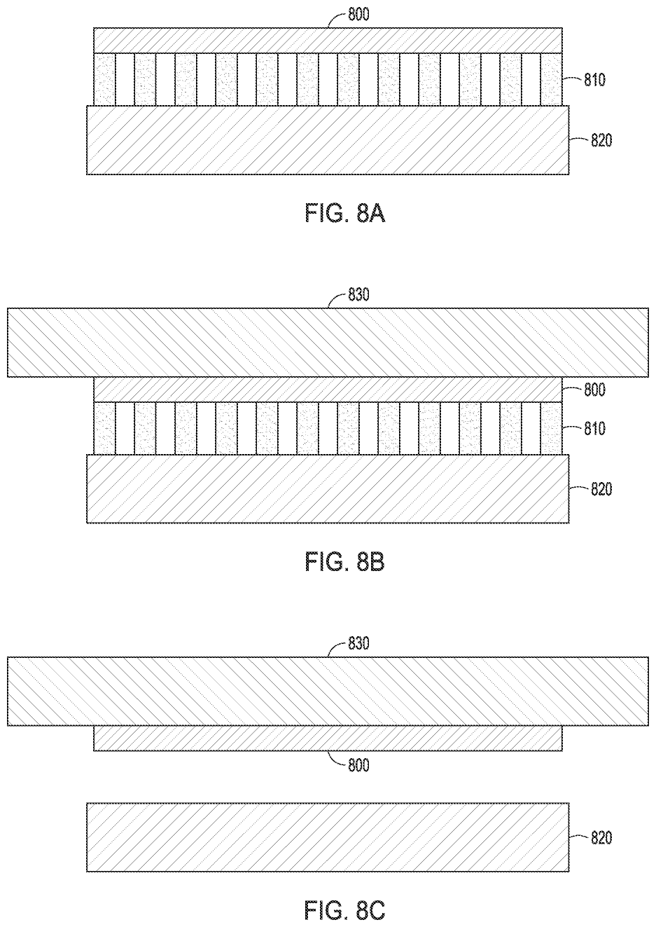

This section describes a method for supporting and carrying the diamond substrate and devices throughout subsequent growth, separation, processing and device deposition. FIG. 8A shows a device substrate layer 800 grown on diamond nanowires 810 that were formed on an original substrate 820. The substrate layer 800 has not yet been separated from the nanowires 810.

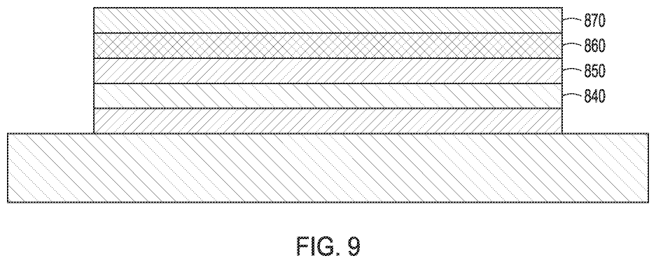

FIG. 8B shows the assembly attached to a polycrystalline diamond plate 830 operating as a holder. Polycrystalline diamond has been selected because it has the exact same expansion coefficient as single crystal and Diamond and is compatible with all chemical and thermal environment to which the single crystal will be exposed. FIG. 8C shows the device substrate 800 attached to the polycrystalline diamond plate 830 operating as a holder or carrier that can be placed in any thermal or chemical environment which can be used for the CVD diamond itself. Plate 830 provides a strong and stable carrier for transporting the assembly through various photolithographic, chemical. transporting, testing and other processing, which may be used for device fabrication. FIG. 9 shows multiple device layers 840, 850, 860, and 870 grown on the device substrate layer 800 coupled to the polycrystalline diamond 830 handle.

In the fulfillment of the process of growing large single crystal diamond substrates, the polycrystalline diamond can be grown by the CVD method or formed from diamond powder by the HPHT process. In addition, at the end of device fabrication, the polycrystalline diamond may be removed, left in place thinned, scribed or processed in a similar manner as other carrier materials in the processing of conventional semiconductor devices.

### EXAMPLES

### Example 1: Growth of Large Area Substrates by SLG

Start with a raw CVD, HPHT or natural diamond crystal

Fabricate a square or rectangular shape from the crystal such that the dimensions that the top, back and edges are all oriented in the (001) plane to within +−5 degrees

For ease of subsequent steps, the rectangular dimensions should be a minimum of 3 mm in length, or more preferably 5 mm, or preferably larger if available.

If the slab is less than 2 mm thick, it should be placed in a cvd reactor and grown to at least 2 mm in thickness. The cvd grower may be selected from among microwave plasma, DC plasma, hot filament and any other appropriate diamond grower.

The slab is laser trimmed so that has near vertical sides if it does not already.

The slab is sliced edgewise to produce a minimum of 3 slabs of a minimum of 100 um thickness

An accurate record is kept of the side and orientation of each slice

The slabs may be mounted on a polishing block and polished flat

The slabs are placed in a cvd grower and held so that they do not move during heating. The cvd grower may be selected from among microwave plasma, DC plasma, hot filament and any other appropriate diamond grower.

The grower with the seeds is heated to growth temperature of between 700 and 1250° C. The growth gas mixture can be from 1% to 10% methane in hydrogen. (or other hydrocarbon gasses giving the same free carbon content).

The nitrogen concentration is maintained between 0.1 and 500 ppm.

CVD diamond growth is carried out to a thickness of 50 to 500 micrometers or more

The slab is removed and inspected for defects. The slabs will be seen to be grown together on the top face and the edges

If the new enlarged slab has defects at the top and side seams. If these are holes or divots they must be removed by polishing, laser trimmed or slab discarded.

Optionally, the slab may be reintroduced to the grower and be grown on the reverse side. This will give additional strength to the slab for subsequent processing. The slab may be polished on both sides for more uniform contact to the grower surface. The edges of the slab may be laser trimmed to remove any defects at the seams.

The slab is then placed in the grower and diamond grown to a minimum of 1 to 2.5 mm thick or more, preferably more than 2.5 mm thick. In the configuration which has been chosen, the diamond crystal will grow laterally at the same rate as it grows perpendicular. Therefore, if the vertical growth was 2.5 mm, the combined lateral growth will be 5 mm. If we started with 5 mm square seeds, the new single crystal slab within the whole slab will be 5 mm×10 mm. It should be noted that this slab within the slab will be one single crystal with no seams!]. [the slabs which were at the ends, have corners which face in the <110> and will grow out of existence, leaving the final growth shape 6 sided with smooth (001) faces and rough (110) edges. Only the interior slab will be free of defective (110) growth. If we had chosen in the beginning, at stage (f), decided to make 4 or more slices, we would have additional single crystal slabs within the larger slab].

The single crystal (s) within the slab is cut out using a laser by cutting from the surface on the original seam. This will produce a thick single crystal slab with no seams.

This slab is sliced from the slab edge to produce a slab of 5 mm×10 mm×100 to 500 um.

This slab is grown to 2.5 mm or greater in thickness

The growth is laser trimmed and sliced as described above.

The new array is grown as described above.

The subsequent slab will contain single crystal slabs having dimensions of 10×10 mm.

This process may be continued to reach one or more inches square.

### Example 2: Separation of Seed and Substrate

The procedure for separation is as follows

Start with a polished diamond crystal with the desired orientation and finish.

Convert the surface of the substrate to diamond nanowires by masking and reactive plasma etching using photolithographically produced masks or self-aligning mask materials. This method produces single crystal nanowires having heights of up to 1 micrometer or more and a diameter of 50 nanometers or more. The array covers the entire upper surface of the seed.

After cleaning, the wafer with the nanowire array is placed in a suitable diamond growing reactor. The cvd grower may be selected from among microwave plasma, DC plasma, hot filament and any other appropriate diamond grower.

With the nano-wire array facing up. The chamber is evacuated, the wafer is heated to the growing temperature and the growth gases introduced to the chamber. Conditions are typically between 900 and 1250° C. (or greater) and methane (or equivalent) concentrations from 1 to 10% (or more).

Growth begins from the tip of the nanowire and spreads linearly with the axis of the wire and laterally, perpendicular to the axis of the wire. Growth only occurs at the tip of the wire and not down the axis of the wire. Growth from adjacent wires meet and since the wires are of exactly the same orientation, form a new continuous single crystal surface. Since lateral growth only occurs at the wire tip. Since there is no lateral growth below the surface, the volume surrounding the wire is a void and only filled with reactor gas.

After growing to the desired thickness, the seed crystal with its new growth is removed from the growth chamber, cleaned and prepared for separation

The seed crystal with its new growth is placed in a furnace containing oxygen or air and heated to 600 to 1200° C. (or more) for 1 to 60 minutes (or more) depending on the temperature.

The oxygen/air penetrates the array of nanowires, which are covered by the single crystal overgrowth, and oxidizes the nanowires to CO and CO2. The wires are preferentially etched compared with the substrate, due the small diameter and large total surface area with respect to their volume.

Once the nanowires are completely etched away, the original seed crystal and the new growth separate.

Since only one micrometer of the original substrate is consumed, the substrate may be used for a repeated growths and replication.

### Example 3: Separation Using Ion Implantation

### Example 4: Separation Using Growth Through Silica Masks

### Example 5: Handling Diamond Wafers

A slab of polycrystalline diamond is chosen which is larger in area than the CVD diamond seed or device slab to be processed. The slab may be CVD or HPHT pressed polycrystalline diamond.

The slab is polished on both sides to be flat, parallel and smooth. Thickness should be no less than 50 um thick and up to 500 um or greater.

The polycrystalline slab is attached to the surface of the single crystal seed by optical contacting, metallization, photoresist glue or any other suitable means.

The polycrystalline slab serves as a handle and carrier through subsequent steps of:

1 Seed separation

2 Device layer growth

3 Heat Treatment

4 Metallization

5 Dicing and thinning

6 Packaging note realignment

### Example 6: Process of Enlarging Diamond Seed Wafer and Growing Device Layers

Produce enlarged diamond seed wafer according to example 1.

Remove large area seed wafer according to example 2 or 3 or 4.

Support and carry seed wafer and device layers according to examples 4 and 5.

Produce diamond layers having purity and doping levels required for the intended devices.

Fabricate and mount diamond devices.

### Example 7: Fused Silica Holder

Method s of example 5 and 6 wherein the holder is fused silica

### Example 8: Silicon Carbide Holder

Method s of example 5 and 6 wherein the holder is silicon carbide.

### Example 9: Silicon Nitride Holder

Method of examples 5 and 6 wherein the holder is silicon nitride

### Example 10: Annealing Diamond Layers

Method of 5 and 6 wherein the polycrystalline diamond substrate and the attached single crystal diamond layers are heat treated to a high temperature, with or without high pressure.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims.

1. A method comprising:
positioning a designated rectangular single crystal diamond seed in a diamond growth reactor, the designated single crystal diamond seed having a (001) plane, with the edges being (001) planes and corners are pointed in the <110> direction;
positioning a pair of blocking seeds on opposite edges of the designated seed; and
growing diamond of the designated seed and blocking seeds, wherein lateral single crystal growth occurs laterally from the designated seed.

2. The method of claim 1 and further comprising:
separating the designated seed and lateral single crystal growth from the blocking seeds and other lateral growth to form a second designated seed having a first pair of opposite edges longer than a second pair of opposite edges; and
repeating growth with new blocking seeds on opposite edges of the second designated seed along opposite longer edges.

3. The method of claim 2 and further comprising repeating the growth and separation of designated seeds until a desired size single crystal diamond substrate is obtained.

4. The method of claim 3 and further comprising:
placing blocking seeds on all four edges of the single crystal diamond substrate; and
growing single crystal diamond on the single crystal diamond substrate while blocking lateral growth.

5. The method of claim 1 wherein the designated seed has edges that are at least 3 mm in length.

6. The method of claim 1 wherein the top, back, and edges of the designated seed are all oriented in the (001) plane to within plus or minus five degrees.

7. The method of claim 1 wherein the designated seed has a thickness of at least 0.05 mm.

8. The method of claim 1 wherein the designated seed and blocking seeds are polished flat prior to growing diamond.

9. The method of claim 1 and further comprising:
following growing, turning the designated seed and blocking seeds with growth over; and
growing diamond on the turned over designated seed and blocking seeds, wherein lateral single crystal growth occurs laterally from the designated seed.

10. The method of claim 4 and further comprising:
creating a nanowire mask the substrate; and
reactive plasma etching the masked substrate to create nanowires as a function of the mask.

11. The method of claim 10 and further comprising:
cleaning the substrate to remove the mask;
growing single crystal diamond on top of the nanowires; and
etching the nanowires to separate the grown single crystal diamond from the substrate.

12. The method of claim 10 wherein the nanowires have a diameter of 50 nanometers or more and a height of up to 1 micrometer.

13. The method of claim 4 and further comprising:
obtaining a slab of polished polycrystalline diamond which is larger than the substrate;
and attaching the slab to the substrate.

14. The method of claim 13 wherein the slab is attached to the substrate by one or more of optical contacting, metallization, or photoresist glue.

15. A method comprising:
creating a nanowire mask on a single crystalline diamond substrate; and
reactive plasma etching the masked substrate to create vertical nanowires as a function of the mask.

16. The method of claim 15 and further comprising:
cleaning the single crystalline diamond substrate to remove the mask;
growing single crystal diamond on top of the nanowires; and
etching the nanowires to separate the grown single crystal diamond from the substrate.

17. The method of claim 15 wherein the nanowires have a diameter of 50 nanometers or more and a height of up to 1 micrometer.

18. The method of claim 17 and further comprising:
obtaining a slab of polished polycrystalline diamond which is larger than the substrate;
and attaching the slab to the substrate.

19. The method of claim 18 wherein the slab is attached to the substrate by one or more of optical contacting, metallization, or photoresist glue.
